(19) United States
(12) Patent Application Publication
(10) Pub. No.: US 2015/0027896 A1
(43) Pub. Date: Jan. 29, 2015

(54) METHOD FOR PRODUCING Cu2ZnSnS4-xSex (0 LESS THAN-EQUAL TO X LESS THAN-EQUAL TO 4) THIN FILM BY ONE STEP ELECTRODEPOSITION IN ELECTROLYTIC BATH CONTAINING IONIC LIQUID

(71) Applicant: KOREA INSTITUTE OF SCIENCE AND TECHNOLOGY, Seoul (KR)

(72) Inventors: Jin Young Kim, Seoul (KR); Doh-Kwon Lee, Seoul (KR); Hong Gon Kim, Seoul (KR); Bong Soo Kim, Seoul (KR); Se Won Seo, Gyeonggi-do (KR); Kee Doo Lee, Seoul (KR); Hae Jung Son, Gyeonggi-do (KR); Min Jae Ko, Cheonan-si (KR)

(73) Assignee: KOREA INSTITUTE OF SCIENCE AND TECHNOLOGY, Seoul (KR)

(21) Appl. No.: 13/975,743

(22) Filed: Aug. 26, 2013

(30) Foreign Application Priority Data
Jul. 25, 2013 (KR) 10-2013-0088012

(51) Int. Cl. H01L 31/18

(52) U.S. Cl. CPC H01L 31/18
USPC 205/177; 205/316; 205/225

(57) ABSTRACT

A Cu₂ZnSnS₄₋ₓSeₓ (0≦x≦4) thin film solar cell is disclosed. The thin film solar cell includes a Cu₂ZnSnS₄₋ₓSeₓ (0≦x≦4) thin film as an absorber layer produced by forming a precursor film composed of Cu, Zn, Sn, and Se using an ionic liquid as a solvent through a constant current process and annealing the precursor film with sulfur. Also disclosed is a method for fabricating the thin film solar cell. The method uses a non-vacuum electrodeposition process that is appropriate for large-area mass production and is thus cost effective compared to a vacuum process. In addition, since the method uses an ionic liquid, the formation of by-products harmful to humans as a result of side reactions is suppressed. Furthermore, the method uses a one-step electrodeposition process, which enables the deposition of a maximum of four elements at one time, or a multi-step deposition process, and an annealing process.

### CROSS-REFERENCE TO RELATED APPLICATIONS

This application claims priority under 35 U.S.C. §119 to Korean Patent Application No. 10-2013-0088012 filed on Jul. 25, 2013 in the Korean Intellectual Property Office, the invention of which is incorporated herein by reference in its entirety.

### BACKGROUND OF THE INVENTION

1. Field of the Invention

The present invention relates to a Cu₂ZnSnS₄₋ₓSeₓ (0≦x≦4) thin film solar cell and a method for fabricating the same. More specifically, the present invention relates to a Cu₂ZnSnS₄₋ₓSeₓ (0≦x≦4) thin film solar cell including a Cu₂ZnSnS₄₋ₓSeₓ (0≦x≦4) thin film as an absorber layer produced by forming a precursor film composed of Cu, Zn, Sn, and Se using an ionic liquid as a solvent through a constant current process and annealing the precursor film with sulfur, and a method for fabricating the thin film solar cell.

2. Description of the Related Art

A great deal of research has been conducted on chalcogenides, such as Cu(In,Ga)Se₂ (CIGS), CdTe, Cu₂ZnSnS₄ (CZTS), and Cu₂ZnSnSe₄ (CZTSe), as materials for absorber layers of semiconductor thin film solar cells. Cu₂ZnSnS₄₋ₓSeₓ (0≦x≦4) (CZT(S,Se)) is non-toxic and uses abundant elements, unlike CdTe and GIGS. In addition, CZT(S,Se) has a direct bandgap of 1.0-1.5 eV and an extinction coefficient as high as 10⁴ cm⁻¹. Due to these advantages, CZT(S,Se) has received attention as a substitute for conventional light absorbers for thin film solar cells.

Chalcogenide-based thin film solar cells have achieved high efficiencies to date. Most of these thin film solar cells utilize vacuum processes. However, such vacuum processes involve considerable costs, which are major obstacles to the commercialization of chalcogenide-based thin film solar cells. In contrast, non-vacuum processes have the advantage that the fabrication costs of chalcogenide-based thin film solar cells can be lowered. Research on the application of non-vacuum processes to the fabrication of chalcogenide-based thin film solar cells is thus needed. Electrodeposition has attracted particular attention as a commercial technique because it involves a low cost, enables large-area deposition, and is recognized as an environmentally friendly technique.

Water is used as a solvent in most electrodeposition processes. However, oxidation and reduction of water are problems encountered in the application of a voltage for electrodeposition. Particularly, reduction of water at a working electrode leads to the generation of hydrogen, which deteriorates the characteristics of films. This problem needs to be solved. The use of a water-free solvent with a broad electrochemical window is required to solve problems associated with the reduction of water.

### SUMMARY OF THE INVENTION

It is an object of the present invention to provide a method for producing a Cu₂ZnSnS₄₋ₓSeₓ (0≦x≦4) thin film by constant-current electrodeposition that is easy to commercialize, a Cu₂ZnSnS₄₋ₓSeₓ (0≦x≦4) thin film solar cell fabricated by using an ionic liquid in place of an aqueous solution, which may deteriorate the quality of the film during constant-current electrodeposition, and a method for fabricating the thin film solar cell.

It is another object of the present invention to provide a method for fabricating a Cu₂ZnSnS₄₋ₓSeₓ (0≦x≦4) thin film solar cell in which reaction products of Sn and Se impeding the formation of a film during electrodeposition of Cu, Zn, Sn, and Se using an ionic liquid are removed, Cu, Zn, Sn, and Se are electrodeposited in one or multiple steps, followed by annealing.

According to one aspect of the present invention, there is provided a CZT(S,Se) thin film solar cell including a) a back electrode layer formed on a glass substrate, b) a CZT(S,Se) photoactive layer formed on the back electrode layer, c) a buffer layer formed on the photoactive layer, d) a window layer for electron collection formed on the buffer layer, and e) a metal grid electrode formed on the window layer.

According to another aspect of the present invention, there is provided a method for fabricating a CZT(S,Se) thin film solar cell, including a) forming a back electrode layer on a glass substrate, b) forming a CZT(S,Se) photoactive layer on the back electrode layer, c) forming a buffer layer on the photoactive layer, d) forming a window layer for electron collection on the buffer layer, and e) forming a metal grid electrode on the window layer.

The method of the present invention uses a non-vacuum electrodeposition process that is appropriate for large-area mass production and is thus cost effective compared to a vacuum process. In addition, since the method of the present invention uses an ionic liquid, the formation of by-products harmful to humans as a result of side reactions is suppressed. Furthermore, the method of the present invention uses a one-step electrodeposition process, which enables the deposition of a maximum of four elements at one time, or a multi-step deposition process, and an annealing process.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1a shows a precursor film formed by one-step electrodeposition of Cu, Zu, Sn, and Se, and FIG. 1b and 1c are XRF data showing the presence of Cu, Zn, Sn, and Se elements in the precursor film; and

FIG. 2 shows (a) a film formed by primary electrodeposition of Cu, Sn, and Se elements, secondary electrodeposition of Zn, and annealing with sulfur, and FIGS. 2b, 2c, and 2d are XRF data showing the presence of Cu, Zn, Sn, and S elements in the precursor film.

### DETAILED DESCRIPTION OF THE INVENTION

Various aspects and embodiments of the present invention will now be discussed in more detail.

One aspect of the present invention provides a method for producing a CZTSe precursor film. The method includes (a1) preparing a CZTSe ionic solution including a Cu precursor, a Zn precursor, a Sn precursor, a Se precursor, and an anhydrous ionic liquid, and (b1) electrodepositing the CZTSe ionic solution on a substrate.

According to the prior art, the application of a voltage in an aqueous solution tends to cause the decomposition of water as a side reaction. In contrast, according to the present invention, no side reaction is caused by the use of a water-free and highly electrochemically stable anhydrous ionic liquid to prevent the performance of the film from deterioration resulting from the reduction of water.

A further aspect of the present invention provides a method for producing a CZTSe precursor film. The method includes (a2) preparing a CZT ionic solution including a Cu precursor, a Zn precursor, a Sn precursor, and an anhydrous ionic liquid, (b2) electrodepositing the CZT ionic solution on a substrate to form a metallic CZT precursor film, and (c2) annealing the CZT precursor film in a Se atmosphere.

Another aspect of the present invention provides a method for producing a CZTSe precursor film. The method includes (a3) preparing a CTSe ionic solution including a Cu precursor, a Sn precursor, a Se precursor, and a first anhydrous ionic liquid, (b3) primarily electrodepositing the CTSe ionic solution on a substrate to form a CTSe precursor film, (c3) preparing a Zn ionic solution including a Zn precursor and a second anhydrous ionic liquid, and (d3) secondarily electrodepositing the Zn ionic solution on the CTSe precursor film.

Another aspect of the present invention provides a method for fabricating a Cu₂ZnSnS₄₋ₓSeₓ thin film solar cell. The method includes (a) producing a CZTSe precursor film by any one of the methods, and (b) annealing the CZTSe precursor film in a sulfur atmosphere to produce a Cu₂ZnSnS₄₋ₓSeₓ (x is a real number from 0 to 4).

In one embodiment, step (a) includes washing and drying the CTZSe precursor film.

Another aspect of the present invention provides CZTSe precursor films produced in accordance with various embodiments of the present invention.

Another aspect of the present invention provides Cu₂ZnSnS₄₋ₓSeₓ thin film solar cells fabricated in accordance with various embodiments of the present invention.

In specific embodiments of the aspects of the present invention, each of the anhydrous ionic liquids may be selected from choline chloride, urea, ethylene glycol, malonic acid, glycerol, and mixtures thereof. The first ionic liquid and the second ionic liquid are identical to or different from each other and may be each independently selected from choline chloride, urea, ethylene glycol, malonic acid, glycerol, and mixtures thereof.

According to various embodiments of the present invention, the anhydrous ionic liquids are free of water. The term “free of water” used herein means that water is not substantially contained at a common sense level in the art (for example, anhydrous ethanol means ethanol free of water) and does not mean that the content of water is numerically limited to exactly zero (0).

Accordingly, it will be obvious based on common knowledge in the art that anhydrous ionic liquids containing about 0-600 ppm water fall within the scope of the anhydrous ionic liquids defined in the present invention.

In a further embodiment, the Cu precursor is a salt including Cu and is preferably selected from copper (II) chloride, copper (II) bromide, copper (II) fluoride, copper (II) nitrate, copper (II) sulfate, copper (II) acetate, and mixtures thereof; the Zn precursor is a salt including Zn and is preferably selected from zinc (II) chloride, zinc (II) bromide, zinc (II) fluoride, zinc (II) nitrate, zinc (II) sulfate, zinc (II) acetate, and mixtures thereof; the Sn precursor is a salt including Sn and is preferably selected from tin (II) chloride, tin (II) bromide, tin (II) fluoride, tin (II) nitrate, tin (II) sulfate, tin (II) acetate, and mixtures thereof; and the Se precursor is a salt including Se and is preferably selected from selenium (IV) chloride, selenium (IV) sulfide, selenic acid, selenium (IV) oxide, and a mixture thereof.

In another embodiment, step (a1) may include (a1′) adding the Sn precursor and the Se precursor to the ionic liquid to prepare a TSe ionic solution, (a1″) removing by-products of reactions between portions of Sn and Se from the TSe ionic solution, and (a1′″) mixing the resulting TSe ionic solution with the Cu precursor and the Zn precursor to prepare a CZTSe ionic solution for electrodeposition.

Step (a2) may include (a2′) adding the Sn precursor to the ionic liquid to prepare a Sn ionic solution, (a2″) removing reaction by-products from the Sn ionic solution, and (a2′″) mixing the resulting Sn ionic solution with the Cu precursor and the Zn precursor to prepare a CZT ionic solution for electrodeposition.

Step (a3) may include (a3′) adding the Sn precursor and the Se precursor to the first ionic liquid to prepare a TSe ionic solution, (a3″) removing reaction by-products from the TSe ionic solution, and (a3′″) mixing the resulting TSe ionic solution with the Cu precursor to obtain a CTSe ionic solution for electrodeposition.

The removal of reaction by-products enables a one-step electrodeposition process by which Cu, Zn, Sn, and Se elements can be deposited simultaneously.

The reaction by-products can be removed by at least one separation technique selected from particle size-based separation techniques, such as filter paper separation, and particle mass-based separation techniques.

In one embodiment, the electrodeposition may be performed by at least one process selected from constant voltage processes using three electrodes and constant current processes using two electrodes. The primary electrodeposition and the secondary electrodeposition may be performed by the same or different processes and may be each independently performed by at least one process selected from constant voltage processes using three electrodes and constant current processes using two electrodes.

A constant current process using two electrodes is more preferred in that it is simple and can be used for mass production.

In a further embodiment, the concentrations of Cu, Zn, Sn, and Se in the CZTSe ionic solution for electrodeposition are 0.01-2 M, 0.01-2 M, 0.01-2 M, and 0.01-2 M, respectively. The concentrations of Cu, Zn, and Sn in the CZT ionic solution for electrodeposition are 0.01-2 M, 0.01-2 M, and 0.01-2 M, respectively. The concentrations of Cu, Sn, and Se in the CTSe ionic solution for electrodeposition are 0.01-2 M, 0.01-2 M, and 0.01-2 M, respectively.

In another embodiment, steps (a1′), (a2′), and (a3′) may be performed at 80 to 90° C., and the substrate may be a glass substrate on which molybdenum is deposited to a thickness of 500 nm to 1 μm.

The present invention will be explained in more detail with reference to the following examples. However, these examples are not to be construed as limiting or restricting the scope and spirit of the invention. It is to be understood that based on the teachings of the present invention including the following examples, those skilled in the art can readily practice other embodiments of the present invention whose specific experimental data are not available.

### EXAMPLES

First, a substrate was prepared. Glass, ceramic, polymer, and stainless steel substrates may be used as materials for the substrate. In this example, a soda-lime glass substrate was used. Various metal elements such as nickel (Ni) and copper (Cu) may be coated on the glass substrate. In this example, molybdenum (Mo) was deposited on the substrate by sputtering. The thickness of the molybdenum deposited was adjusted to the range of 500 nm to 1 μm.

Then, an electrolytic bath containing an ionic liquid as a solvent was prepared. Electrodeposition was performed in the electrolytic bath. Various ionic liquids may be used. In this example, a solution of choline chloride in ethylene glycol was used as the ionic liquid. The temperature was maintained at 85° C. until use.

SnCl₂ and SeCl₄ were added in amounts such that their concentrations became 0.2 M. At this time, by-products were formed as a result of reactions between Sn and Se. The by-products may be removed by various methods. In this example, by-products were removed using a filter paper.

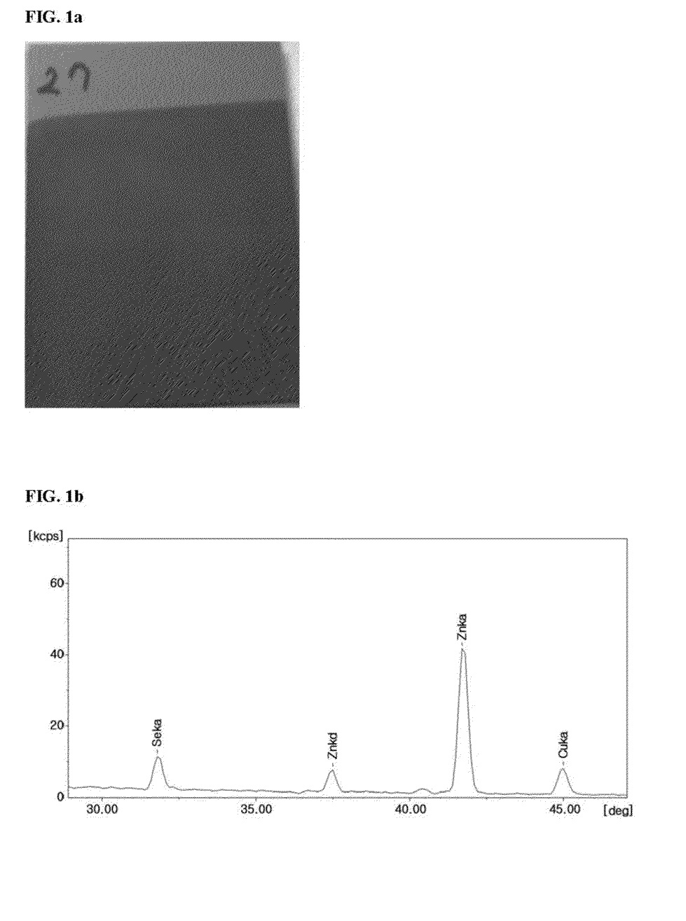

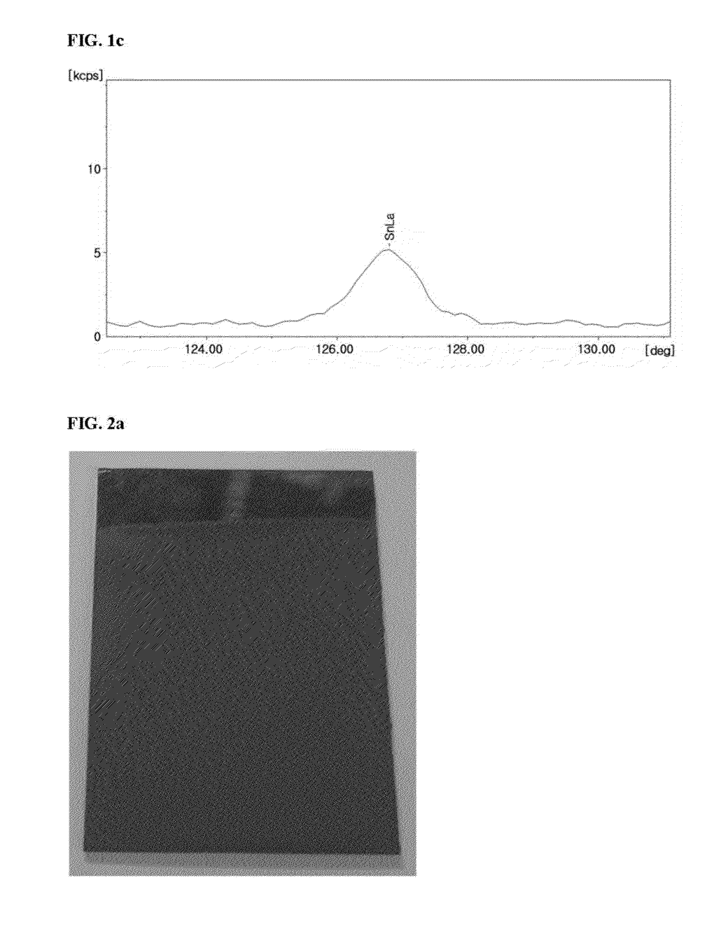

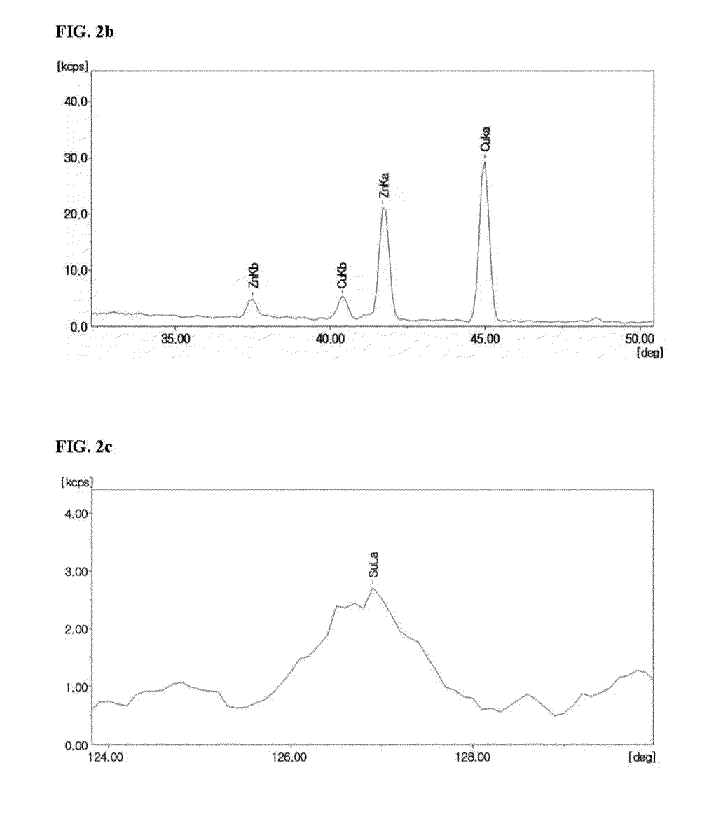

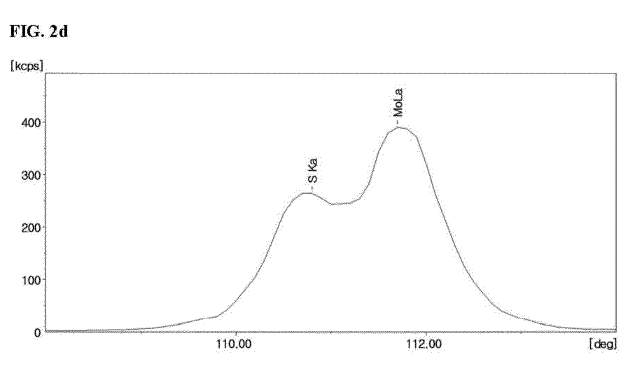

To the resulting ionic solution, CuCl₂ and ZnCl₂ were added in amounts such that the CuCl₂, ZnCl₂, SnCl₂, and SeCl₄ concentrations became 0.03 M, 0.05 M, 0.02 M, and 0.02 M, respectively. However, the concentrations of the precursors in the mixture may be changed to vary the composition of the constituent elements of a final CZT(S,Se) precursor. For multi-step electrodeposition, three of the four elements can be electrodeposited at one time, and then the other element can be electrodeposited (FIG. 1a).

Next, electrodeposition was performed using the substrate and the electolytic bath at a constant current. Various metals may be used as materials for a counter electrode. In this example, a platinum electrode was used as a counter electrode. For film uniformity, the current and time may be varied depending on the concentration of the solution in the electrolytic bath. In this example, electrodeposition was performed while applying a current of 15 mA for 3 min to deposit all elements. The electrodeposited CZTSe precursor was rinsed with water and dried using nitrogen gas.

Next, the CZTSe precursor film was annealed in a sulfur atmosphere to form a CZT(S,Se) film. For annealing, an electric furnace having two heating zones was used. The sulfur atmosphere may be created by various methods. In this example, the sulfur atmosphere was created by placing a sulfur powder in one of the heating zones, vaporizing the sulfur powder by heating, and allowing argon gas to flow into the heating zone. The CZTSe precursor film was placed in the other heating zone and annealed at 500-600° C. for 10 min.

Then, a buffer layer was formed on the CZT(S,Se) film. The buffer layer serves to reduce the differences in pn junction, lattice constant and energy bandgap between the absorber layer and a window layer. CdS or ZnS may be used to form the buffer layer. In this example, CdS was subjected to chemical bath deposition to form the CdS buffer layer having a thickness of 50-60 nm.

Thereafter, a window layer was deposited on the buffer layer. The window layer may be formed using a material having a high transmittance and a high electrical conductivity as an n-type semiconductor. In this example, the window layer was deposited by sputtering of i-ZnO and Al:ZnO.

Subsequently, a grid electrode for current collection was deposited on the window layer. The grid electrode was formed by vaporization of Ni/Al.

1. A method for producing a CZTSe precursor film, the method comprising
(a1) preparing a CZTSe ionic solution comprising a Cu precursor, a Zn precursor, a Sn precursor, a Se precursor, and an anhydrous ionic liquid, and
(b1) electrodepositing the CZTSe ionic solution on a substrate.

2. A method for producing a CZTSe precursor film, the method comprising
(a2) preparing a CZT ionic solution comprising a Cu precursor, a Zn precursor, a Sn precursor, and an anhydrous ionic liquid,
(b2) electrodepositing the CZT ionic solution on a substrate to form a CZT precursor film, and
(c2) annealing the CZT precursor film in a Se atmosphere.

3. A method for producing a CZTSe precursor film, the method comprising
(a3) preparing a CTSe ionic solution comprising a Cu precursor, a Sn precursor, a Se precursor, and a first anhydrous ionic liquid,
(b3) primarily electrodepositing the CTSe ionic solution on a substrate to form a CTSe precursor film,
(c3) preparing a Zn ionic solution comprising a Zn precursor and a second anhydrous ionic liquid, and
(d3) secondarily electrodepositing the Zn ionic solution on the CTSe precursor film.

4. The method according to claim 3, wherein the anhydrous ionic liquid is selected from choline chloride, urea, ethylene glycol, malonic acid, glycerol, and mixtures thereof,
the first ionic liquid and the second ionic liquid are identical to or different from each other and are each independently selected from choline chloride, urea, ethylene glycol, malonic acid, glycerol, and mixtures thereof, and
the Cu precursor is selected from copper (II) chloride, copper (II) bromide, copper (II) fluoride, copper (II) nitrate, copper (II) sulfate, copper (II) acetate, and mixtures thereof, the Zn precursor is selected from zinc (II) chloride, zinc (II) bromide, zinc (II) fluoride, zinc (II) nitrate, zinc (II) sulfate, zinc (II) acetate, and mixtures thereof, the Sn precursor is selected from tin (II) chloride, tin (II) bromide, tin (II) fluoride, tin (II) nitrate, tin (II) sulfate, tin (II) acetate, and mixtures thereof, and the Se precursor is selected from selenium (IV) chloride, selenium (IV) sulfide, selenic acid, selenium (IV) oxide, and a mixture thereof.

5. The method according to claim 4, wherein step (a1) comprises (a1′) adding the Sn precursor and the Se precursor to the ionic liquid to prepare a TSe ionic solution, (a1″) removing by-products of reactions between portions of Sn and Se from the TSe ionic solution, and (a1′″) mixing the resulting TSe ionic solution with the Cu precursor and the Zn precursor to prepare a CZTSe ionic solution for electrodeposition,
step (a2) comprises (a2′) adding the Sn precursor to the ionic liquid to prepare a Sn ionic solution, (a2″) removing reaction by-products from the Sn ionic solution, and (a2′″) mixing the resulting Sn ionic solution with the Cu precursor and the Zn precursor to prepare a CZT ionic solution for electrodeposition, and
step (a3) comprises (a3′) adding the Sn precursor and the Se precursor to the first ionic liquid to prepare a TSe ionic solution, (a3″) removing reaction by-products from the TSe ionic solution, and (a3′″) mixing the resulting TSe ionic solution with the Cu precursor to obtain a CTSe ionic solution for electrodeposition.

6. The method according to claim 5, wherein the electrodeposition is performed by at least one process selected from constant voltage processes using three electrodes and constant current processes using two electrodes, and
the primary electrodeposition and the secondary electrodeposition are performed by the same or different processes and are each independently performed by at least one process selected from constant voltage processes using three electrodes and constant current processes using two electrodes.

7. The method according to claim 6, wherein the concentrations of Cu, Zn, Sn, and Se in the CZTSe ionic solution for electrodeposition are 0.01-2 M, 0.01-2 M, 0.01-2 M, and 0.01-2 M, respectively,
the concentrations of Cu, Zn, and Sn in the CZT ionic solution for electrodeposition are 0.01-2 M, 0.01-2 M, and 0.01-2 M, respectively,
the concentrations of Cu, Sn, and Se in the CTSe ionic solution for electrodeposition are 0.01-2 M, 0.01-2 M, and 0.01-2 M, respectively,
steps (a1′), (a2′), and (a3′) are performed at 80 to 90° C., and the substrate is a glass substrate on which molybdenum is deposited to a thickness of 500 nm to 1 μm.

8. A method for fabricating a Cu₂ZnSnS₄₋ₓSeₓ thin film solar cell, the method comprising
(a) producing a CZTSe precursor film by the method according to claim 1, and
(b) annealing the CZTSe precursor film in a sulfur atmosphere to produce a Cu₂ZnSnS₄₋ₓSeₓ (x is a real number from 0 to 4).

9. The method according to claim 8, wherein step (a) comprises washing and drying the CTZSe precursor film.

10. The method according to claim 8, wherein the anhydrous ionic liquid is selected from choline chloride, urea, ethylene glycol, malonic acid, glycerol, and mixtures thereof,
the first ionic liquid and the second ionic liquid are identical to or different from each other and are each independently selected from choline chloride, urea, ethylene glycol, malonic acid, glycerol, and mixtures thereof, and
the Cu precursor is selected from copper (II) chloride, copper (II) bromide, copper (II) fluoride, copper (II) nitrate, copper (H) sulfate, copper (II) acetate, and mixtures thereof, the Zn precursor is selected from zinc (II) chloride, zinc (II) bromide, zinc (II) fluoride, zinc (II) nitrate, zinc (II) sulfate, zinc (II) acetate, and mixtures thereof, the Sn precursor is selected from tin (H) chloride, tin (II) bromide, tin (II) fluoride, tin (II) nitrate, tin (II) sulfate, tin (II) acetate, and mixtures thereof, and the Se precursor is selected from selenium (IV) chloride, selenium (IV) sulfide, selenic acid, selenium (IV) oxide, and a mixture thereof.

11. The method according to claim 10, wherein step (a1) comprises (a1′) adding the Sn precursor and the Se precursor to the ionic liquid to prepare a TSe ionic solution, (a1″) removing by-products of reactions between portions of Sn and Se from the TSe ionic solution, and (a1′″) mixing the resulting TSe ionic solution with the Cu precursor and the Zn precursor to prepare a CZTSe ionic solution for electrodeposition,
step (a2) comprises (a2′) adding the Sn precursor to the ionic liquid to prepare a Sn ionic solution, (a2″) removing reaction by-products from the Sn ionic solution, and (a2′″) mixing the resulting Sn ionic solution with the Cu precursor and the Zn precursor to prepare a CZT ionic solution for electrodeposition, and
step (a3) comprises (a3′) adding the Sn precursor and the Se precursor to the first ionic liquid to prepare a TSe ionic solution, (a3″) removing reaction by-products from the TSe ionic solution, and (a3′″) mixing the resulting TSe ionic solution with the Cu precursor to obtain a CTSe ionic solution for electrodeposition.

12. The method according to claim 11, wherein the electrodeposition is performed by at least one process selected from constant voltage processes using three electrodes and constant current processes using two electrodes, and
the primary electrodeposition and the secondary electrodeposition are performed by the same or different processes and are each independently performed by at least one process selected from constant voltage processes using three electrodes and constant current processes using two electrodes.

13. The method according to claim 12, wherein the concentrations of Cu, Zn, Sn, and Se in the CZTSe ionic solution for electrodeposition are 0.01-2 M, 0.01-2 M, 0.01-2 M, and 0.01-2 M, respectively,
the concentrations of Cu, Zn, and Sn in the CZT ionic solution for electrodeposition are 0.01-2 M, 0.01-2 M, and 0.01-2 M, respectively,
the concentrations of Cu, Sn, and Se in the CTSe ionic solution for electrodeposition are 0.01-2 M, 0.01-2 M, and 0.01-2 M, respectively,
steps (a1′), (a2′), and (a3′) are performed at 80 to 90° C., and
the substrate is a glass substrate on which molybdenum is deposited to a thickness of 500 nm to 1 μm.

14. (canceled)

15. (canceled)
